(19) United States
(12) Patent Application Publication
(10) Pub. No.: US 2007/0102697 A1
(43) Pub. Date: May 10, 2007

(54) JUNCTION STRUCTURE OF ORGANIC SEMICONDUCTOR DEVICE, ORGANIC THIN FILM TRANSISTOR AND FABRICATING METHOD THEREOF

(76) Inventors: Fang-Chung Chen, Taichung City (TW); Chiao-Shun Chuang, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,092

(22) Filed: Nov. 10, 2005

(51) Int. Cl. H01L 29/08

(52) U.S. Cl. 257/40; 257/E29.16

(57) ABSTRACT

A junction structure of an organic semiconductor device including an organic semiconductor layer, a conductive layer and a modifying layer is provided. The modifying layer is formed between the organic semiconductor layer and the conductive layer, wherein the modifying layer includes an inorganic compound or an organic complex compound. An organic thin film transistor including a gate, a source/drain, a dielectric layer, an organic semiconductor layer and at least a modifying layer is also provided. The gate is electrically isolated from the source/drain. The dielectric layer is disposed between the gate and the source/drain. The organic semiconductor layer is disposed between the source and the drain. The modifying layer is disposed between the organic semiconductor layer and the source/drain, wherein the modifying layer includes an inorganic compound or an organic complex compound.

### BACKGROUND OF THE INVENTION

1. Field of the Invention

The present invention generally relates to a semiconductor device and a fabricating method thereof. More particularly, the present invention relates to an organic thin film transistor and a fabricating method thereof.

2. Description of Related Art

Because the organic semiconductor device can be formed on a flexible plastic substrate or a metal substrate, it has advantages of light weight, low cost and flexibility. Thus, organic thin film transistors have been in valued in recent years.

In fabricating methods of the organic thin film transistor, the material for the source/drain is usually metal, such as gold, palladium or platinum. The junction between an electrode made of these metals and an organic semiconductor is Schottky contact, and thus a higher junction resistance is existed. Several methods have been disclosed to resolve the problem of high contact resistance in the organic thin film transistor. For example, a method of doping impurities in the junction between the metal electrode and the organic semiconductor is disclosed in the prior art. However, the organic semiconductor doped with impurities has poor stability. Another conventional method is forming a buffer layer having high carrier density between the organic semiconductor and the metal electrode. Fermi level of the buffer layer is between the levels of the organic semiconductor layer and the metal electrode so as to reduce the energy barrier when carriers inject into the organic semiconductor from the metal electrode. However, this method causes the reduction of the on-off ratio of the organic thin film transistor.

In the references of U.S. Pat. No. 6,335,539 B1 and U.S. Pat. No. 6,569,707 B2, a thiol compound is formed on the metal electrode to form a self-assembled monolayer so as to reduce the junction resistance in the organic thin film transistor. However, only a few of metals (metal electrode) can be used in this method. In addition, the self-assembled monolayer formed on the metal electrode is formed by immersion method. Hence, this method can only be applied to particular type organic thin film transistors.

### SUMMARY OF THE INVENTION

Accordingly, the present invention is directed to a junction structure of an organic semiconductor device capable of reducing the junction resistance in the organic semiconductor device.

The present invention is directed to an organic thin film transistor and a fabricating method thereof capable of reducing the junction resistance in the organic thin film transistor.

A junction structure of an organic semiconductor device is provided. The junction structure includes an organic semiconductor layer, a conductive layer and a modifying layer. The modifying layer is formed between the organic semiconductor layer and the conductive layer, wherein the material for the modifying layer comprises an inorganic compound or an organic complex compound.

According to an embodiment of the present invention, said material for the organic semiconductor layer comprises a small molecule organic semiconductor, a polymer semiconductor or an oligomer semiconductor.

According to an embodiment of the present invention, said material for the conductive layer comprises a metal, a metal oxide or a conductive polymer.

According to an embodiment of the present invention, said inorganic compound comprises LiF, CsF, LiO₂, LiBO₂, K₂SiO₃, Cs₂CO₃ or Al₂O₃.

According to an embodiment of the present invention, said organic complex compound comprises CH₃COOLi , CH₃COONa, CH₃COOK, CH₃COORb or CH₃COOCs.

An organic thin film transistor including a gate, a source/drain, a dielectric layer, an organic semiconductor layer and at least a modifying layer is also provided. The gate is electrically isolated from the source/drain. The dielectric layer is disposed between the gate and the source/drain. The organic semiconductor layer is disposed between the source and the drain. The modifying layer is disposed between the organic semiconductor layer and the source/drain, wherein the material for the modifying layer comprises an inorganic compound or an organic complex compound.

According to an embodiment of the present invention, said material for the gate comprises a metal, a metal oxide, a conductive polymer or a doped silicon material.

According to an embodiment of the present invention, said material for the source/drain comprises a metal, a metal oxide, a conductive polymer or a doped silicon material.

According to an embodiment of the present invention, said the dielectric layer comprises SiO₂, Si₃N₄, TiO₂, LaO₂, Al₂O₃, polyimide, polymethylmethacrylate, polyamide or parylene.

According to an embodiment of the present invention, said the material for the organic semiconductor layer comprises a small molecule organic semiconductor, a polymer semiconductor or an oligomer semiconductor.

According to an embodiment of the present invention, said inorganic compound comprises LiF, CsF, LiO₂, LiBO₂, K₂SiO₃, Cs₂CO₃ or Al₂O₃.

According to an embodiment of the present invention, said organic complex compound has a formula of RX, wherein R is an organic function group and X is a metal element. For example, the organic complex compound comprises CH₃COOLi , CH₃COONa, CH₃COOK, CH₃COORb or CH₃COOCs.

According to an embodiment of the present invention, said gate is formed under the source/drain.

According to an embodiment of the present invention, said the gate is formed above the source/drain. In another embodiment, the organic thin film transistor further comprises another gate formed under the source/drain.

In addition, a method for forming an organic thin film transistor is also provided. The method includes forming a gate, a dielectric, an organic semiconductor layer and a source/drain, characterized in that forming a modifying layer between the organic semiconductor layer and the source/drain, wherein the material for the modifying layer comprises an inorganic compound or an organic complex compound.

According to an embodiment of the present invention, the method for forming the modifying layer comprises performing a depositing process with a shadow mask.

According to an embodiment of the present invention, the method for forming the modifying layer comprises performing a depositing process collocated with a photolithography and etching process.

Since the modifying layer made of an inorganic compound or an organic complex compound is formed between the organic semiconductor layer and the conductive layer, the junction resistance between the organic semiconductor layer and the conductive layer can be reduced.

The modifying layer formed between the organic semiconductor layer and the conductive layer is made of inorganic compound or an organic complex compound so that it can be applied to various organic thin film transistors.

The modifying layer formed between the organic semiconductor layer and the conductive layer is formed through a shadow mask or photolithography and etching process so that it can be applied to various organic thin film transistors.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-section view showing a junction structure of an organic semiconductor device according to an embodiment of the present invention.

FIG. 2 is a cross-section view showing an organic thin film transistor according to an embodiment of the present invention.

FIGS. 3-7 are cross-section views showing other organic thin film transistors according to embodiments of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

Junction Structure of an Organic Semiconductor Device

FIG. 1 is a cross-section view showing a junction structure of an organic semiconductor device according to an embodiment of the present invention. As shown in FIG. 1, the junction structure of an organic semiconductor device includes an organic semiconductor layer 40, a conductive layer 55 and a modifying layer 60. The organic semiconductor device is, for example, a metal-oxide-semiconductor (MOS) device, a metal-insulator-semiconductor (MIS) device, a thin film transistor (TFT) or an organic thin film transistor (OTFT). In an embodiment, the material for the organic semiconductor layer 40 comprises a small molecule organic semiconductor, a polymer semiconductor or an oligomer semiconductor. The small molecule organic semiconductor is, for example, tetracene, pentacene or phthalocyanine. The polymer semiconductor is, for example, polythiophene, polyfluorene, polyphenylenevinylene or a derivative thereof, such as poly(3-octyl)thiophene, poly(dioctylfluroene) or poly[2-methoxy-5-(2′-ethyl-hexyloxy)-1,4-phenylenevinylene]. The oligomer semiconductor is, for example, α-sexithiophene.

As shown in FIG. 1, the material for the conductive layer 55 is, for example, a metal, a metal oxide or a conductive polymer. The metal can be aluminium, titanium, nickel, copper, gold or chromium, for example. The metal oxide can be, for example, indium stannum oxide or indium zinc oxide. The conductive polymer can be, for example, a mixture of 3,4-polyethylenedioxythiophene and polystyrenesulfonate (PEDOT:PSS) or polyaniline.

In order to reduce the junction resistance between the conductive layer 55 and the organic semiconductor layer 40, a modifying layer 60 is formed therebetween. The material for the modifying layer 60 comprises an inorganic compound or an organic complex compound. The inorganic compound can be, for example, LiF, CsF, LiO₂, LiBO₂, K₂SiO₃, Cs₂CO₃, Al₂O₃ and the like. The organic complex compound has a formula of RX, wherein R is an organic function group, such as CH₃COO—, and X is a metal element. For example, the organic complex compound comprises CH₃COOLi , CH₃COONa, CH₃COOK, CH₃COORb or CH₃COOCs.

The efficiency of that carriers inject into the organic semiconductor layer 40 form the conductive layer 55 can be improved because of the formation of the modifying layer 60, and the junction resistance between the organic semiconductor layer 40 and the conductive layer 55 can be reduced.

Organic Thin Film Transistor

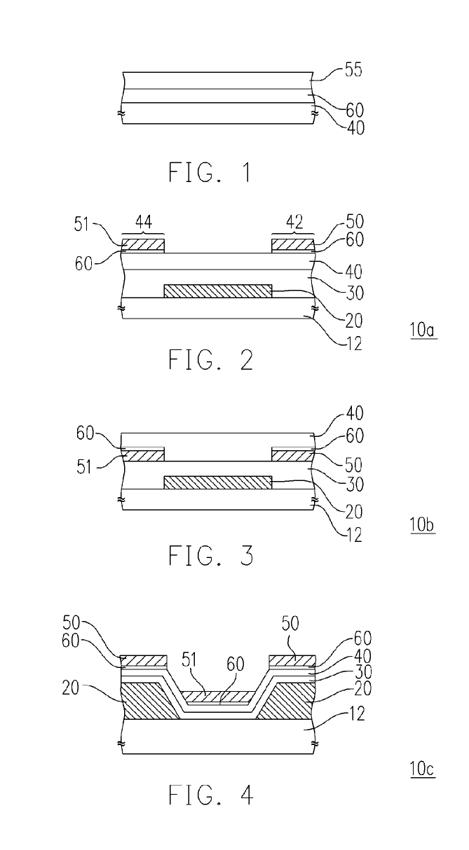

FIG. 2 is a cross-section view showing an organic thin film transistor according to an embodiment of the present invention. As shown in FIG. 2, the organic thin film transistor 10a comprises a gate 20, a source 50 and a drain 51, a dielectric layer 30, an organic semiconductor layer 40 and at least a modifying layer 60. The organic thin film transistor 10a is a bottom gate thin film transistor, and thus the gate 20 is formed under the source 50 and the drain 51. The dielectric layer 30 is formed between the gate 20 and the source 50/drain 51 so as to isolate the gate 20 and the source 50/drain 51. The organic semiconductor layer 40 is formed between the source 50 and the drain 51 so as to form a semiconductor channel. In addition, the modifying layer 60 is formed between the organic semiconductor layer 40 and the source 50/drain 51 to reduce the junction resistance between the organic semiconductor layer 40 and the source 50/drain 51. In particular, the material for the modifying layer 60 comprises an inorganic compound or an organic complex compound.

The fabricating method for the thin film transistor 10a is first providing a substrate 12, such as a glass substrate, a sapphire substrate, a semiconductor substrate or a polymer plastic substrate. The semiconductor substrate, for example, is germanium silicide (SiGe) or a semiconductor doped with P or N type impurities. The polymer plastic substrate is, for example, polyethylene teraphthalate (PET) or polycarbonate (PC).

Next, as shown in FIG. 2, a gate 20 is formed on the substrate 12. The material for the gate 20 includes, for example, a metal, a metal oxide, a conductive polymer or a doped silicon material. The metal can be aluminium, titanium, nickel, copper, gold or chromium, for example. The metal oxide can be, for example, indium stannum oxide or indium zinc oxide, for example. The conductive polymer can be, for example, a mixture of 3,4-polyethylenedioxythiophene and polystyrenesulfonate (PEDOT:PSS) or polyaniline. Thereafter, a dielectric layer 30 is formed over the substrate 12 and the gate 20. The material for the dielectric layer 30 comprises silicon oxide (SiO₂), silicon nitride (Si₃N₄), titanium oxide (TiO₂), lanthanum oxide (LaO₂), aluminum oxide (Al₂O₃), polyimide, polymethylmethacrylate, polyamide or parylene. Then, an organic semiconductor layer 40 is formed on the dielectric layer 30. The material for the organic semiconductor layer 40 comprises a small molecule organic semiconductor, a polymer semiconductor or an oligomer semiconductor. The small molecule organic semiconductor is, for example, tetracene, pentacene or phthalocyanine. The polymer semiconductor is, for example, polythiophene, polyfluorene, polyphenylenevinylene or a derivative thereof, such as poly(3-octyl)thiophene, poly(dioctylfluroene) or poly[2-methoxy-5-(2′-ethyl-hexyloxy)-1,4-phenylenevinylene]. The oligomer semiconductor is, for example, α-sexithiophene.

Thereafter, a modifying layer 60 is formed on the organic semiconductor layer 40. The modifying layer 60 can be formed by performing a depositing process with a shadow mask so as to form the modifying layer 60 covering the first region 42 and the second region 44. Then, a source 50 and a drain 51 are formed in the first region 42 and the second region 44 by using the same shadow mask. The modifying layer 60 formed between the organic semiconductor layer 40 and the source 50/drain 51 can improve the efficiency of that carriers (electrons or holes) inject into the organic semiconductor layer 40 from the source 50 and the drain 51, and the junction resistance between the organic semiconductor layer 40 and the source 50/drain 51 can be reduced. In addition, the modifying layer 60 formed in the first and second regions 42, 44 can also be formed by a depositing process collocated with a photolithography and etching process, and then the source 50 and the drain 51 are formed on the modifying layer 60 using a photo-mask that is the same to that used in the photolithography process for the modifying layer 60. The material for the modifying layer 60 comprises an inorganic compound or an organic complex compound. The inorganic compound can be, for example, lithium fluoride (LiF), cesium fluoride (CsF), lithium oxide (LiO₂), lithium boron oxide (LiBO₂), potassium sulfite (K₂SiO₃), cesium carbonate (Cs₂CO₃), aluminum oxide (Al₂O₃) and the like. The organic complex compound has a formula of RX, wherein R is an organic function group, such as acetate (CH₃COO—), and X is a metal element. For example, the organic complex compound comprises CH₃COOLi , CH₃COONa, CH₃COOK, CH₃COORb or CH₃COOCs. The material for the source 50 and the drain 51 includes, for example, a metal, a metal oxide, a conductive polymer or a doped silicon material.

It should be noted that the material for the modifying layer 60 formed in the first region 42 can also be different from that of the modifying layer 60 formed in the second region 44. For example, the modifying layer 60 formed in the first region 42 is LiF while the modifying layer 60 formed in the second region 44 is CsF. In addition, the modifying layer 60 formed between the organic semiconductor layer 40 and the source 50/drain 51 can also be a multi-layer structure.

The modifying layer can also be applied to other type organic thin film transistors. FIGS. 3-7 are cross-section views showing other organic thin film transistors according to embodiments of the present invention. Because the modifying layer 60 can be formed through a depositing process with a shallow mask or a depositing process collocated with a photolithography and etching process, it is applied to various organic thin film transistors.

As shown in FIG. 3, the organic thin film transistor 10b formed on a substrate 12 comprises a gate 20, a source 50 and a drain 51, a dielectric layer 30, an organic semiconductor layer 40 and at least a modifying layer 60. The gate 20 is formed under the source 50 and the drain 51, and thus the organic thin film transistor 10b is also a bottom gate thin film transistor. In particular, the organic semiconductor layer 40 and the modifying layer 60 are disposed over the source 50 and the drain 51.

Please refer to FIG. 4, the gate 20 is formed under the source 50 and the drain 51, and thus the organic thin film transistor 10c is also a bottom gate thin film transistor. In particular, the source 50 and the drain 51 are formed at two levels. Hence, a vertical channel is formed from the organic semiconductor layer 40.

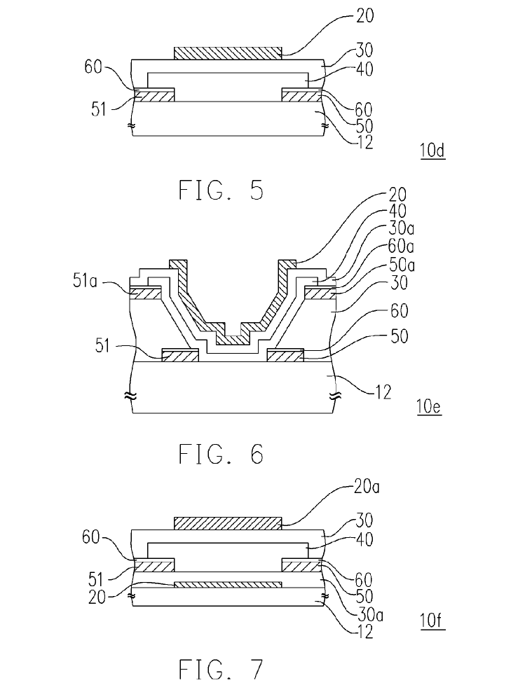

As shown in FIG. 5, the organic thin film transistor 10d formed on a substrate 12 comprises a gate 20, a source 50 and a drain 51, a dielectric layer 30, an organic semiconductor layer 40 and at least a modifying layer 60. The gate 20 is formed above the source 50 and the drain 51, and thus the organic thin film transistor 10d is a top gate thin film transistor.

As shown in FIG. 6, the organic thin film transistor 10e formed on a substrate 12 comprises a gate 20, a first source 50 and a first drain 51, a first dielectric layer 30, an organic semiconductor layer 40, a second source 50a and a second drain 51a, a second dielectric layer 30a, at least a first modifying layer 60 and at least a second modifying layer 60a. The gate 20 is disposed above the first source 50/drain 51 and the second source 50a/drain 51a, and thus the organic thin film transistor 10e is a top gate thin film transistor. In particular, the first source 50/drain 51 and the second source 50a/drain 51a are not disposed at the same level, and thus a vertical channel is formed from the organic semiconductor layer 40.

Please refer to FIG. 7, the organic thin film transistor 10f formed on a substrate 12 comprises a first gate 20, a source 50 and a drain 51, a first dielectric layer 30, an organic semiconductor layer 40, a second dielectric layer 30a, at least a modifying layer 60 and a second gate 20a. The organic thin film transistor 10f is a double gate thin film transistor. The first gate 20 is formed above the source 50 and the drain 51 while the second gate 20a is formed under the source 50 and the drain 51.

The modifying layer made of the inorganic compound or organic complex compound used in the organic semiconductor device can reduce the junction resistance. In addition, the modifying layer can be applied to various organic thin film transistors having different organic semiconductor layer.

The modifying layer is formed by performing a depositing process with a shadow mask or a depositing process collocated with a photolithography and etching process. Hence, the modifying layer can be formed in various type organic thin film transistors.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A junction structure of an organic semiconductor device, comprising:
an organic semiconductor layer;
a conductive layer; and
a modifying layer between the organic semiconductor layer and the conductive layer, wherein the material for the modifying layer comprises an inorganic compound or an organic complex compound.

2. The junction structure of an organic semiconductor device according to claim 1, wherein the material for the organic semiconductor layer comprises a small molecule organic semiconductor, a polymer semiconductor or an oligomer semiconductor.

3. The junction structure of an organic semiconductor device according to claim 1, wherein the material for the conductive layer comprises a metal, a metal oxide or a conductive polymer.

4. The junction structure of an organic semiconductor device according to claim 1, wherein inorganic compound comprises LiF, CsF, LiO₂, LiBO₂, K₂SiO₃, Cs₂CO₃ or Al₂O₃.

5. The junction structure of an organic semiconductor device according to claim 1, wherein the organic complex compound comprises CH₃COOLi , CH₃COONa, CH₃COOK, CH₃COORb or CH₃COOCs.

6. An organic thin film transistor, comprising:
a gate and a source/drain, wherein the gate is electrically isolated from the source/drain;
a dielectric layer, disposed between the gate and the source/drain;
an organic semiconductor layer, disposed between the source and the drain; and
at least a modifying layer, disposed between the organic semiconductor layer and the source/drain, wherein the material for the modifying layer comprises an inorganic compound or an organic complex compound.

7. The organic thin film transistor according to claim 6, wherein the material for the gate comprises a metal, a metal oxide, a conductive polymer or a doped silicon material.

8. The organic thin film transistor according to claim 6, wherein the material for the source/drain comprises a metal, a metal oxide, a conductive polymer or a doped silicon material.

9. The organic thin film transistor according to claim 6, wherein the dielectric layer comprises SiO₂, Si₃N₄, TiO₂, LaO₂, Al₂O₃, polyimide, polymethylmethacrylate, polyamide or parylene.

10. The organic thin film transistor according to claim 6, wherein the material for the organic semiconductor layer comprises a small molecule organic semiconductor, a polymer semiconductor or an oligomer semiconductor.

11. The organic thin film transistor according to claim 6, wherein inorganic compound comprises LiF, CsF, LiO₂, LiBO₂, K₂SiO₃, Cs₂CO₃ or Al₂O₃.

12. The organic thin film transistor according to claim 6, wherein the organic complex compound has a formula of RX, wherein R is an organic function group and X is a metal element.

13. The organic thin film transistor according to claim 12, wherein the organic complex compound comprises CH₃COOLi , CH₃COONa, CH₃COOK, CH₃COORb or CH₃COOCs.

14. The organic thin film transistor according to claim 6, wherein the gate is formed under the source/drain.

15. The organic thin film transistor according to claim 6, wherein the gate is formed above the source/drain.

16. The organic thin film transistor according to claim 15, further comprises another gate formed under the source/drain.

17. A method for forming an organic thin film transistor comprising forming a gate, a dielectric, an organic semiconductor layer and a source/drain, characterized in that:
forming a modifying layer between the organic semiconductor layer and the source/drain, wherein the material for the modifying layer comprises an inorganic compound or an organic complex compound.

18. The method for forming an organic thin film transistor according to claim 17, wherein the method for forming the modifying layer comprises performing a depositing process with a shadow mask.

19. The method for forming an organic thin film transistor according to claim 17, wherein the method for forming the modifying layer comprises performing a depositing process and a photolithography and etching process.
